(19) United States
(12) Patent Application Publication
(10) Pub. No.: US 2013/0120727 A1
(43) Pub. Date: May 16, 2013

(54) EXPOSURE SYSTEM

(71) Applicants: Hans Opower, Krailling (DE); Klaus Juenger, Hennef (DE)

(72) Inventors: Hans Opower, Krailling (DE); Klaus Juenger, Hennef (DE)

(73) Assignee: KLEO AG, Appenzell (CH)

(21) Appl. No.: 13/470,580

(22) Filed: May 14, 2012

Related U.S. Application Data
(63) Continuation of application No. PCT/EP2010/067010, filed on Nov. 8, 2010.

(30) Foreign Application Priority Data
Nov. 18, 2009 (DE) 10 2009 046 809.9

(51) Int. Cl. G03F 7/20

(52) U.S. Cl. CPC G03F 7/20
USPC 355/67

(57) ABSTRACT

An exposure system for generating exposed structures in a photosensitive layer arranged on an object is provided. The exposure system has an object carrier accommodating the object and an exposure device, which are movable relative to one another. Exposure beams exit from the exposure device, with each of which an exposure spot can be generated on the photosensitive layer by means of an imaging unit in a position controlled manner. At least one first exposure unit generating a set of first exposure beams and at least one second exposure unit generating a set of second exposure beams is associated with at least one deflecting element, first and second exposure beams of these exposure units being deflectable by the same deflecting element. Mirror surface areas for the first exposure beams and for the second exposure beams are arranged on the deflecting element offset relative to one another in a row direction.

This application is a continuation of International application No. PCT/EP2010/067010 filed on Nov. 8, 2010 and claims the benefit of German application No. 10 2009 046 809.9 filed on Nov. 18, 2009, the teachings and disclosures of which are hereby incorporated in their entirety by reference thereto.

### BACKGROUND OF THE INVENTION

The invention relates to an exposure system for generating exposed structures in a photosensitive layer arranged on an object, comprising an object carrier accommodating the object and an exposure device, wherein the object carrier and the exposure device are movable relative to one another in a direction of feed and wherein exposure spots can be generated on the photosensitive layer with the exposure device transversely to the direction of feed in a position controlled manner in that the exposure device has at least one exposure unit with a row of radiation exit areas which are arranged so as to follow one another in a row direction and from which exposure beams exit, with each of which an exposure spot can be generated on the photosensitive layer by means of an imaging unit and each of which can be deflected in a direction of deflection which extends transversely to the row direction and at an angle to the direction of feed by means of at least one deflecting unit which has a deflecting element which moves in a direction of movement and has at least one reflector surface so that with each exposure beam exposure spots, which overlap one another at least partially, can be generated in the direction of deflection in a plurality of consecutive exposure spot positions. Exposure systems of this type are known from the state of the art, for example from WO 2008/071347.

The problem with such exposure systems is to arrange the exposure units and the deflecting units relative to one another as compactly as possible since the deflection of the individual exposure beams in the direction of deflection is relatively small and, in addition, the number of exposure beams which can be generated per exposure device is likewise subject to technical limitations.

### SUMMARY OF THE INVENTION

This object is accomplished in accordance with the invention, in an exposure system of the type described at the outset, in that at least one first exposure unit generating a set of first exposure beams and at least one second exposure unit generating a set of second exposure beams are associated with the at least one deflecting element, the first and second exposure beams of said exposure units being deflectable by the same deflecting element during its movement and that the movable deflecting element is provided with at least one mirror surface area for each first and for each second exposure beam from the respective first set and second set and that the mirror surface areas for the first exposure beams and the mirror surface areas for the second exposure beams are arranged on the deflecting element so as to be offset relative to one another in the row direction.

The advantage of the solution according to the invention is to be seen in the fact that, with it, it is possible to deflect the sets of exposure beams of at least two exposure units with one deflecting unit and, therefore, achieve as compact a construction as possible.

Due to the fact that the direction of deflection extends at an angle to the direction of feed, it is possible to expose exposure spots which are located next to one another transversely to the direction of feed by means of the various exposure beams of the at least one exposure unit at the same time despite the direction of deflection extending transversely to the row direction.

One particularly favorable solution provides for the mirror surface areas to have an offset in the row direction which corresponds at least to a distance between two consecutive exposure beams of one set of exposure beams.

Such an offset makes it possible to arrange the exposure spot positions on the photosensitive layer in an optimum manner.

It is even better when the offset corresponds to a multiple of the distance between two consecutive exposure beams of one set of exposure beams.

With respect to the construction of the deflecting elements, no further details have so far been given.

It is of advantage to mount the deflecting elements on oppositely located sides in order to ensure a precise alignment of the deflecting elements.

Since the deflecting elements must not only be mounted but must also be driven in order to move them in the direction of movement, one particularly favorable solution provides for the deflecting elements to be drivable by a drive device on one side.

One particularly advantageous and compact construction of an exposure system according to the invention results when deflecting elements which are arranged so as to follow one another in a transverse direction extending transversely to the direction of feed can be alternatingly driven with a drive device on respective, oppositely located sides.

As a result, the drive devices may be arranged relative to one another in a particularly space-saving manner.

A further, advantageous embodiment of the exposure system according to the invention provides for the mirror surface areas of the first and second exposure beams of the first and second exposure units to be arranged with respect to an area of alignment on the photosensitive layer extending at right angles to the direction of feed such that one of the exposure spot positions of one of the paths of deflection of the first exposure unit and an exposure spot position corresponding thereto of the corresponding path of deflection of the second exposure unit are located in this area of alignment.

The area of alignment can have an extension which corresponds at the most to a twentieth of an extension of the deflecting element in the direction of feed.

However, in order to have the individual exposure units positioned relative to one another in a particularly exact manner, it is preferably provided for the area of alignment to have, in the direction of feed, an extension which corresponds to a distance between the last exposure spot position of one of the paths of deflection and the first exposure spot position of the next one of the paths of deflection of a set of exposure beams.

Alternatively or in addition to the features of the exposure system according to the invention described above, an additional, advantageous embodiment provides for at least one first exposure unit generating a set of first exposure beams and at least one second exposure unit generating a set of second exposure beams to be associated with the at least one deflecting element, the first and second exposure beams of these exposure units being deflectable by the same deflecting element during its movement, and for the first and the second exposure beams to impinge on the photosensitive layer offset relative to one another in a row direction extending transversely to the direction of movement.

This solution has the advantage that the exposure units may be arranged relative to one another and to the deflecting unit in an optimum manner, as a result.

In this respect, it is particularly favorable when all the exposure units of the exposure device are arranged relative to one another such that exposure spot positions of corresponding paths of deflection, these spot positions corresponding to one another, are located on the photosensitive layer in an area of alignment which extends at right angles to the direction of feed.

In this case, as well, the area of alignment can have an extension which corresponds at the most to a twentieth of the extension of the deflecting element in the direction of feed.

It is, however, particularly favorable when the area of alignment has an extension in the direction of feed which corresponds to a distance between the last exposure spot position of one of the paths of defection and the first exposure spot position of the next path of deflection of one of the exposure units in the direction of feed.

With such a solution, an adequately small deviation of the position of the exposure units relative to one another will be achieved and this makes the determination of the areas to be exposed on the photosensitive layer simple to carry out.

An additional, advantageous embodiment of an exposure system according to the invention provides for the exposure spot positions of the sets of first and second exposure beams respectively corresponding to one another to have a distance from a line of alignment, which extends at right angles to the direction of feed, which corresponds at the most to the diameter of an exposure spot of the exposure spot position.

A further, advantageous solution provides for a line of alignment which extends through one of the exposure spot positions of one of the paths of deflection of the first exposure unit and is aligned at right angles to the direction of feed to intersect an exposure spot position of the corresponding path of deflection of the second exposure unit which corresponds thereto and so the two exposure units are positioned exactly relative to one another in such a manner that it is very easy to expose the structures to be exposed.

In the case of the exposure system according to the invention, it could be provided for the at least one set of first and the at least one set of second exposure beams to impinge on the same longitudinal side of the deflecting element and be reflected by the mirror surface areas formed on this longitudinal side.

Another preferred solution provides for the at least one set of first exposure beams to impinge on one of the longitudinal sides of the deflecting element and the at least one set of second exposure beams to impinge on a longitudinal side located opposite the one longitudinal side.

The advantage of this solution is to be seen in the fact that, with it, the exposure units for generating the first exposure beams and the exposure units for generating the second exposure beams can be arranged in an optimum space-saving manner and, in particular, be arranged such that at least sections thereof are located on oppositely located sides of the deflecting element.

Within the scope of this solution it is, therefore, conceivable for several sets of first exposure beams and several sets of second exposure beams to impinge on the deflecting element.

Alternatively or in addition to the solutions described above, the object specified at the outset is also accomplished by an exposure system of the type specified at the outset, wherein, in accordance with the invention, a respective one from each of at least two sets of exposure beams impinges on the same mirror surface area of the deflecting element and is reflected by it onto the photosensitive layer.

The advantage of this solution is to be seen in the fact that, with it, a very compact solution is provided, in particular, for high resolutions and likewise offers the possibility of exposing the photosensitive layer in an area-covering and simple manner.

In this respect, it is favorable when the exposure beams impinge on the same mirror surface area at an acute angle relative to one another so that the two exposure beams are deflected by the mirror surface area in different directions and, therefore, exposure spots arranged at different locations on the photosensitive layer result.

One particularly expedient solution provides for the exposure beams to extend symmetrically to a central axis.

In this respect, the exposure beams can be deflected such that the exposure spots of a respective one of the exposure beams can be moved along a corresponding path of deflection, wherein the paths of deflection preferably extend parallel to one another but are not flush with one another.

One particularly favorable solution provides for the at least two exposure beams to generate exposure spots on the photosensitive layer which are located on a common line of deflection.

In this respect, the exposure spots of the individual exposure beams could be arranged on the line of deflection such that the exposure spots of one of the exposure beams are located on one section of the line of deflection and the exposure spots of the other one of the exposure beams are located on another section of the line of deflection. As a result, it is, however, possible for a space to remain between the sections of the line of deflection and so the row of exposure spots of the one exposure beam and the row of exposure spots of the other exposure beam do not merge into one another.

In order to have them merging into one another, it is preferably provided for the last exposure spot of the one exposure beam to be arranged in such a manner that it overlaps at least partially with the first exposure spot of the other exposure beam so that, altogether, the two sections of the path of deflection also merge into one another in an overlapping manner and it is, therefore, possible with the exposure spots of the exposure beams to carry out exposure continuously over an entire path of deflection and, therefore, create a coherent exposed area.

One particularly expedient solution provides, in addition, for the exposure beams to result in exposure spots, of which respectively adjacent exposures spots overlap at least partially.

It is also ensured with this condition that the exposure spots of the exposure beams can be used to form a coherent exposed area along a path of deflection.

It is, in addition, advantageous when the exposure spots of consecutive exposure beams of the at least one exposure unit can be moved along directions of deflection which are parallel to one another since, as a result, a simple simultaneous positioning of the exposure spots which can be generated by the various exposure beams can be realized.

Furthermore, it is favorable when the exposure beams of the at least one exposure unit can be deflected by the deflecting unit at the same time and to the same extent so that, as a result, the positioning of the exposure spots generated by these exposure beams will be simplified since the relative position of the exposure spots is determined in a defined manner for a control unit.

In order to also influence the photochemical processes in the photosensitive layer, where possible, to the same extent and also obtain photochemical conversion processes which are as identical as possible with all the exposure beams, it is preferably provided for the exposure beams of one exposure unit to impinge on the photosensitive layer aligned essentially parallel to one another so that no varying effects can occur as a result of the alignment of the exposure beams.

Furthermore, it is favorable when the movement of each exposure spot generated by an exposure beam is brought about in the respective direction of deflection via a path of deflection which is approximately of the same length for each exposure beam of the exposure unit. As a result, the positioning of the exposure spots can be determined and carried out in a simple manner by means of the control unit.

In order to make it possible for the exposure spots generated by different exposure beams to be positionable such that coherent structures, in particular with a component in a transverse direction, can be generated with the exposure spots of different exposure beams, it is preferably provided for the exposure spot of the last exposure spot position of the one path of deflection and the exposure spot of the first exposure spot position of the next path of deflection following on in the row direction to be arranged with respect to a straight reference line which extends parallel to the direction of feed in such a manner that the straight reference line intersects the exposure spots generated in these exposure spot positions.

It is ensured by this condition that the exposure spots of the last exposure spot position and the one exposure beam and the first exposure spot position of the next exposure beam following on in the row direction are arranged relative to one another transversely to the direction of feed such that they overlap at least slightly with suitable displacement in the direction of feed.

It is particularly favorable when a straight reference line extending parallel to the direction of feed through the last exposure spot position of a path of deflection intersects the exposure spot of a first exposure spot position of a next following path of deflection.

It is ensured by this condition—when it is assumed that a central point of the respective exposure spot is to be taken as exposure spot position—that the two exposure spots overlap at least approximately by half with suitable displacement in the direction of feed, a condition which is advantageous when a coherent structure is intended to be generated in the photosensitive layer over and beyond the exposure spots of different paths of deflection.

It is even more favorable when the first exposure spot position of the next following path of deflection has a distance from the straight reference line which corresponds at the most to half the diameter of the exposure spot so that the overlapping of the two exposure spots is even greater, i.e. at least half the diameter, normally, however, more than this.

In order to be able to generate as many exposure spots as possible at the same time within the scope of the solution according to the invention, it is preferably provided for several exposure units to be provided, wherein the exposure units are arranged at a distance from one another in the direction of deflection.

Furthermore, it is provided in the case of such several exposure units for the directions of deflection of the several exposure units to extend parallel to one another so that, as a result, the determination of the individual exposure spot positions can be carried out more easily and efficiently for the control unit.

The several exposure units could be arranged relative to one another such that the row directions of consecutive exposure units extend at an angle to one another.

Furthermore, it is provided in one embodiment for the row directions of the several exposure units to extend essentially parallel to one another so that, finally, the individual rows in the several exposure units are also aligned essentially parallel to one another.

In order to also be able to generate coherent structures with the exposure spots generatable in the case of several exposure units, it is provided for the several exposure units to be arranged with respect to a straight reference line extending parallel to the direction of feed such that the straight reference line intersects the exposure spot of the last exposure spot position of the last path of deflection of one exposure unit and the exposure spot of the first exposure spot position of the first path of deflection of the next exposure unit following on in the direction of deflection or in a transverse direction. As a result, at least a slight overlapping of the two exposure spots is also ensured in order to be able to generate coherent structures, which extend in the transverse direction with at least one component, with the exposure spots of different exposure units.

The overlapping is, however, even better when the straight reference line extending through the last exposure spot position of a last path of deflection of one exposure unit intersects the exposure spot of the first exposure spot position of a first path of deflection of a next exposure unit following on in a direction of deflection or transverse direction so that proceeding from the fact that the exposure spot position is defined by the central point of the respective exposure spot, the two exposure spots overlap at least approximately by half.

A further condition expedient for the overlapping provides for the first exposure spot position to have a distance from the straight reference line which corresponds at the most to half the diameter of the exposure spot of the first exposure spot position.

With respect to the deflecting units, no further details have so far been given.

It would, in principle, be conceivable within the scope of the solution according to the invention to provide a separate deflecting unit for each exposure beam, wherein the deflecting units could also operate differently.

As a solution favorable for reasons of the production of such an exposure system it is provided for the deflecting unit to have a mirror surface area for each of the exposure beams.

In this respect, the individual mirror surface areas can still be movable independently of one another. For reasons of a simplification of the construction, it is, however, favorable when the mirror surface areas of one exposure unit can be moved together.

The mirror surface areas may be realized particularly favorably when the mirror surface areas are sections of a common mirror surface.

In order to achieve a deflection with these mirror surface areas, it is favorable when the mirror surface areas can be tilted onto the exposure beams relative to the direction of impingement thereof since such a tilting movement of the mirror surface areas can be realized mechanically in a simple manner.

In principle, the mirror surface areas can be curved in order to be able to implement focusing with them, for example, at the same time but a solution, with which the mirror surface areas are flat surface areas, is constructionally particularly simple.

It is constructionally particularly favorable when all the mirror surface areas are located in a common plane which simplifies the implementation of the titling movement.

With this solution, it is particularly favorable to arrange the mirror surface areas such that the mirror surface areas, onto which the exposure beams of one exposure unit impinge, are located in the same plane.

In order to bring about as efficient a deflection of the respective exposure beam as possible, it is provided for the exposure unit to have several mirror surface areas for each exposure beam.

In this respect, it is particularly favorable when the deflecting unit has for each exposure beam several mirror surface areas which are used one after the other for deflecting the exposure beam so that each exposure beam will be deflected by a plurality of mirror surface areas which are used one after the other.

Such a number of several mirror surface areas may be realized constructionally in a simple manner when the several mirror surface areas are formed by circumferential sides of a mirror body arranged so as to be rotatable.

The mirror body could still be tiltable oscillatingly about an axis.

It is, however, particularly favorable in order to achieve as great a deflecting speed as possible when the mirror body is arranged so as to rotate constantly about an axis.

In this case, the mirror surface areas are expediently arranged at the same radial distance around the axis, wherein the mirror surface areas preferably extend parallel to the axis.

In order to be able to allocate the position of the mirror surfaces to respectively corresponding exposure spot positions in a defined manner, it is preferably provided for the mirror body to rotate about its axis with a constant rotational speed.

No further details have been given within the scope of the solution according to the invention as to how the exposure beams exiting from the radiation exit areas are intended to be generated. For example, the radiation exit areas can be direct exit areas of radiation sources, for example laser diodes.

It is, however, even more advantageous when the radiation exit areas are ends of optical fibers.

As a result, it is possible to arrange the radiation areas and the radiation sources separately from one another.

However, in order to be able to control the intensity in each individual radiation area in a concerted manner, it is provided for a separate radiation source to be associated with each optical fiber so that as a result of the intensity control of this radiation source, whether it be as a result of intensity control of the radiation source itself or of a subsequent intensity control element, the intensity exiting from the radiation exit areas can be controlled.

In this respect, a laser, which is preferably a semiconductor laser for reasons of a simple construction, is likewise preferably provided as radiation source.

In this respect, it is particularly favorable when the radiation sources are arranged in a radiation generating unit which is arranged separately from the exposure device since it is then possible to cool the radiation sources efficiently and, in particular, there is no risk of thermal problems with respect to the exactness of the exposure spot positions, which can be generated by the exposure device, resulting on account of the heat developed by the radiation sources.

Additional features and advantages of the solution according to the invention are the subject matter of the following description as well as the drawings illustrating one embodiment.

### BRIEF DESCRIPTION OF THE DRAWINGS

FIG. 1 shows a schematic perspective illustration of a first embodiment of an exposure system according to the invention;

FIG. 2 shows an enlarged illustration of a section of an object with a photosensitive layer arranged on an object carrier and, where applicable, structures to be generated in it;

FIG. 3 shows a schematic sectional illustration of a section of an exposure area, in which exposure spots can be generated;

FIG. 4 shows a schematic illustration of a section of two deflecting units with exposure units associated with them;

FIG. 5 shows a section along line 5-5 in FIG. 4;

FIG. 6 shows a schematic enlarged illustration of a function of one of the deflecting units in FIG. 4 with the migration of the two exposure beams in a direction of deflection;

FIG. 7 shows an enlarged sectional illustration of exposure spot positions and exposure spots which can be generated by two exposure beams of an exposure unit;

FIG. 8 shows an illustration of the exposure spot positions which can be generated, similar to FIG. 3, with the illustration of mirror bodies of the deflecting units and an area of alignment;

FIG. 9 shows a schematic enlarged illustration of exposure units of the exposure device arranged next to one another with the associated deflecting units in a section along line 8-8 in FIG. 1;

FIG. 10 shows an illustration similar to FIG. 6 of a second embodiment and

FIG. 11 shows an illustration similar to FIG. 7 of the second embodiment.

### DETAILED DESCRIPTION OF THE INVENTION

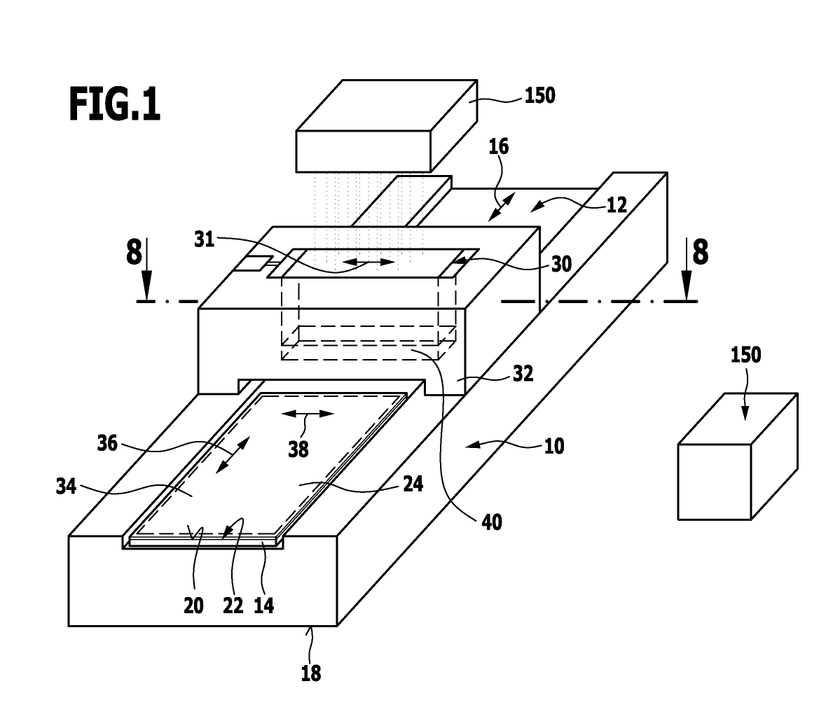

A first embodiment of an exposure device illustrated in FIG. 1 comprises a machine base which is designated as a whole as 10 and has a guide 12, along which an object carrier 14 is guided for movement in the direction of a direction of feed 16, on the one hand, and, on the other hand, is preferably movable by drives, for example linear drives, in a positionally exact manner.

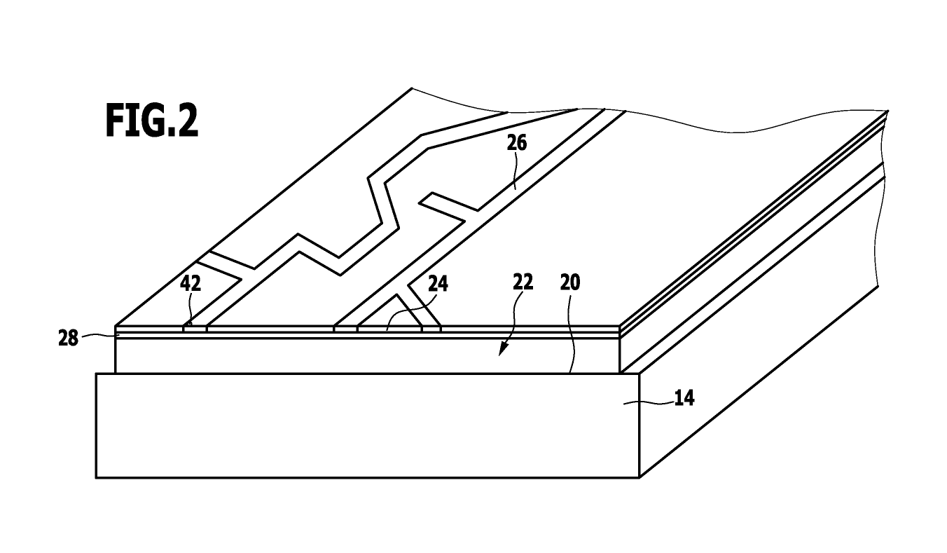

The guide 12 is arranged, for example, on a side of the machine base 10 which faces way from a floor space 18 and guides the object carrier 14 in such a manner that an object 22 can be placed and fixed in position on its upper side 20 which faces away from the machine base 10, as illustrated in FIG. 2, this object being provided on its side again facing away from the object carrier 14 with a photosensitive layer 24, in which structures 26 can be generated by means of suitable exposure by way of optical conversion of the material of the photosensitive layer 24.

For example, structures 26 of this type serve the purpose of selectively covering individual areas of a layer 28, for example a copper layer 28 of the object 22, in order to then remove the layer 28 at the places, at which it is not covered by the structures 26, within the scope of, for example, an etching procedure so that the layer 28 remains only in those areas, in which it is covered by the structures 26.

The production of the structures 26 illustrated in FIG. 2 by way of optical conversion of the photosensitive layer 24 is brought about by an exposure device which is designated as a whole as 30 and is arranged on a bridge 32, which is supported on the machine base 10 on both sides of the guide 12 and, in addition, extends over and beyond the guide 12, so that it can be moved and positioned in a direction of adjustment 31 extending transversely to the direction of feed 16.

In the embodiment illustrated, it is possible with the exposure device 30 according to the invention, during a single movement of the object carrier 14 with the object 22 with the photosensitive layer 24, to provide the photosensitive layer within a structure area 34 with all the structures 26 provided in this structure area 34 by way of exposure during the course of this single movement of the photosensitive layer 24 in the direction of feed 16, wherein the exposure device 30 is in a position to expose the structure area 34 not only in its longitudinal direction 36 but also in its transverse direction 38 in one go during the course of the single movement of the photosensitive layer 24 in the direction of feed 16 in order to provide all the structures 26 provided and required within the structure area 34 without further movements of the object carrier 14 in the direction of feed 16 being necessary.

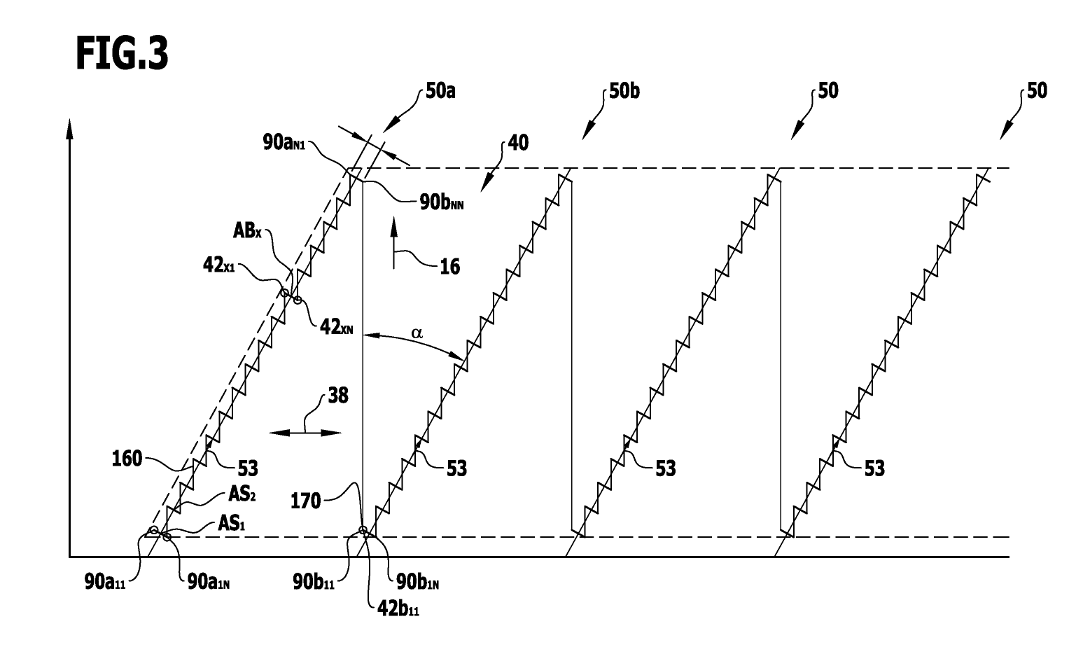

In order to be able to generate all the required structures 26 within this structure area 34, individual exposure spots 42 can be generated within an exposure area 40 which is associated with the exposure device 30 and illustrated in FIG. 1 and partially in FIG. 3 and these exposure spots are arranged within the exposure area 40 in such a manner that the sum of all the exposure spots 42 present in the exposure area 40 comprises all those exposure spots 42 which are necessary to generate, in the transverse direction 38, a linear structure which extends over the entire extension of the structure area 34 in the transverse direction 38 and is continuous in the transverse direction 38 without interruption, for which purpose the exposure spots 42 are to be arranged such that these exposure spots 42 which follow one another in the transverse direction 38 overlap.

This means, in other words, that the exposure spots 42 which can be generated within the exposure area 40 have such a size and are arranged in such a manner that all possible structures 26 can be generated with them, taking into consideration the movement of the object 22 in the direction of feed 16, in a manner covering the entire area of the structure area 34 of the photosensitive layer 24 within the scope of the resolution which is conditional on the areal extension of the exposure spots 42 in the longitudinal direction 36 and the transverse direction 38.

It is, however, also conceivable in a modification of the first embodiment to move the object carrier 14 one time in the direction of the direction of feed 16 and another time contrary thereto so that proceeding from a starting position illustrated in FIG. 1, a movement of the object carrier 14 back and forth leads to the desired, comprehensive exposure in the structure area 34 and so it would be conceivable, for example, during the course of a movement in the direction of the direction of feed 16, when seen in the transverse direction 38, to expose half the structure area 34 in a first position of the exposure device 30 in the direction of adjustment 31 by means of a smaller selected exposure area 40 and the other half following displacement of the exposure device 30 together with the exposure area 40 associated with it in a countermove into a second position in the direction of adjustment 31.

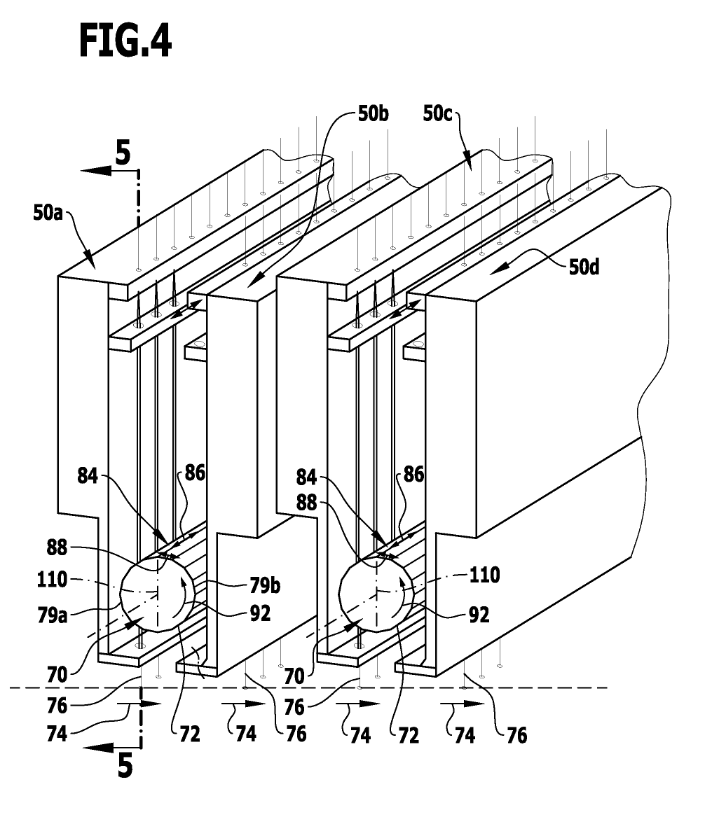

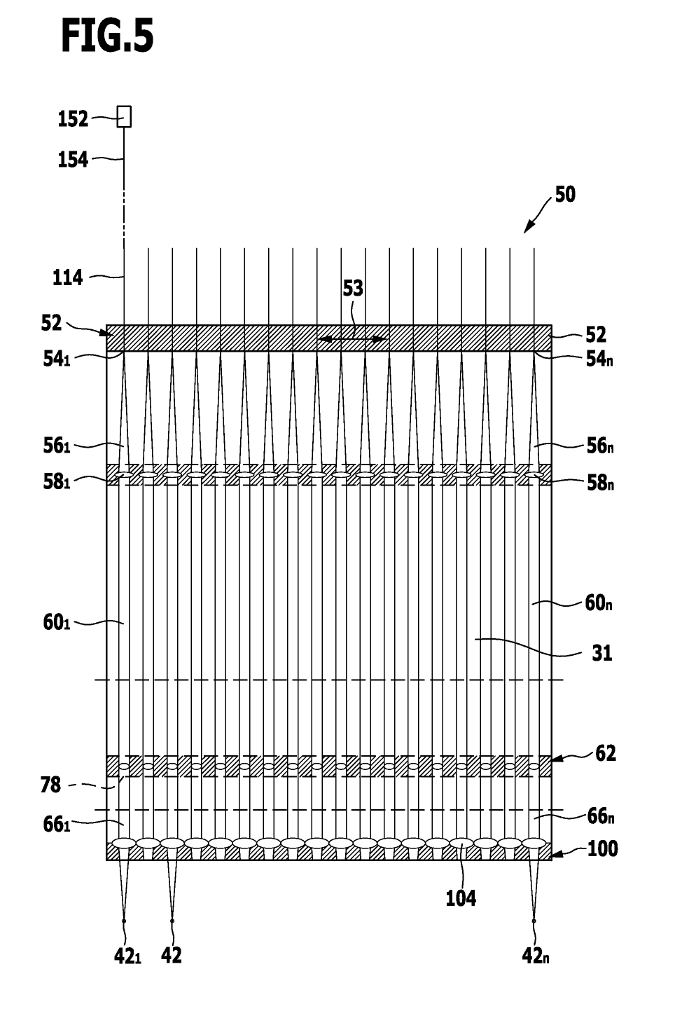

In order to be able to generate the exposure spots 42 in the required number and position within the exposure area 40, several exposure units 50 are provided in the exposure device 30, as illustrated in FIG. 4, and each of them, as illustrated in FIG. 5, has a row of radiation exit areas 54 which are arranged at a distance from one another and following one another in a row direction 53 and from each of which radiation beams 56 exit which are converted by optical devices 58 into collimated exposure beams 60, wherein the collimated exposure beams 60, as illustrated in FIGS. 4 and 5, form a set 61 of exposure beams 60 and are deflected by a deflecting unit 62 transversely to their direction of propagation, wherein each set impinges on a deflecting unit 70 which is illustrated in FIG. 4 and has a deflecting element 72 which, as illustrated in FIG. 4, deflects the collimated exposure beams 60 into exposure beams 76 migrating in a direction of deflection 74 transverse to the row directions.

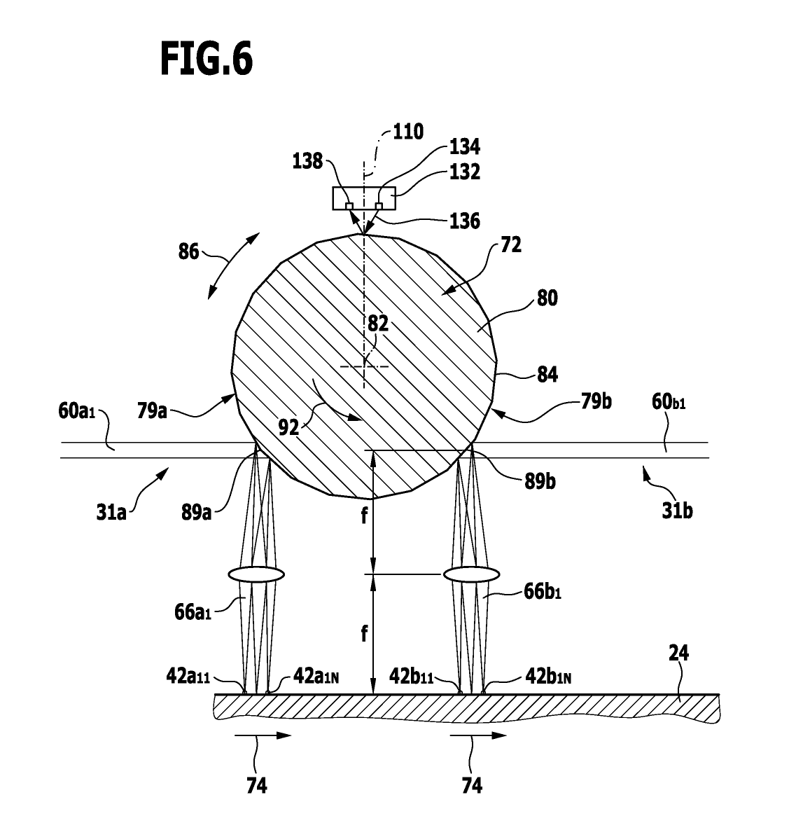

The deflecting unit 70 comprises as deflecting element 72, for example, a mirror body 80 which has mirror surfaces 84 which are arranged symmetrically to an axis 82 and extend parallel to the axis 82 and which are preferably arranged on the outer casing of the mirror body 80 (FIG. 6).

Preferably, the mirror surfaces 84 essentially adjoin one another in circumferential direction 86 and extend in their longitudinal direction 86 as well as in their transverse direction 88 over the same length and breadth, respectively, so that all the mirror surfaces 84 have the same extension.

In addition, all the mirror surfaces 84 are flat surfaces and so the mirror body 70 has, in the simplest case, a cross sectional surface which is that of a regular polygon, wherein the number of mirror surfaces 84 is, for example, greater than 4 and smaller than 100.

One preferred embodiment provides for the number of mirror surfaces 84 to be greater than 30 and smaller than 50.

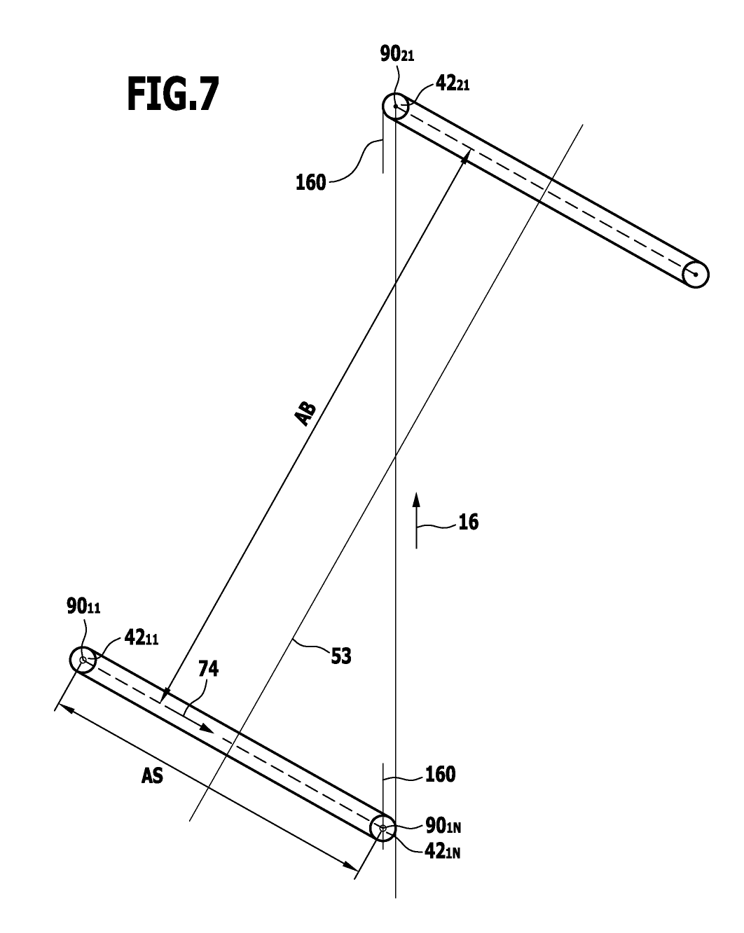

Each of the mirror surfaces 84, with a respective mirror surface area 89, reflects a respective collimated exposure beam 60 of the respective set 61 of exposure beams 60 deflected by the deflecting unit 62 in accordance with the respective rotary position of the mirror body 80 in such a manner that, as illustrated in FIGS. 6 and 7, in a first position of the mirror surface 84, for example, the first migrating exposure beam 66₁ of the set 61 generates an exposure spot 42₁₁ in a first exposure spot position 90₁₁ which then migrates further in the direction of the direction of deflection 74 via a path of deflection AS as far as a last nth exposure spot position 90_{1N} which corresponds to the position of the respective mirror surface 84, in which the exposure beam 60₁ still impinges on an actively used area of the mirror surface 84 and, therefore, is still reflected by it for generating the exposure spot 42_{1N} associated with the last exposure spot position 90_{1N}.

Further turning of the mirror body 80 in the direction of rotation 92 leads to the exposure beam 60₁ impinging on the actively used area of the next mirror surface 84 which then reflects the exposure beam 60₁ into the migrating exposure beam 66₁ again such that this, on the other hand, generates the exposure spot 42₁₁ in the first exposure spot position 90₁₁.

As a result, the constant rotation of the mirror body 80 about the axis 82 leads to a constant migration of the exposure spots 42ₓ₁ generated by an exposure beam 60ₓ from the first exposure spot position 90ₓ₁ as far as the last nth exposure spot position 90_{xN} via the paths of deflection AS on the photosensitive layer 24.

It is, therefore, possible to carry out exposure of the photosensitive layer 24 in the area of the path of deflection AS along the direction of deflection 68 by means of the exposure spots 42ₓ in exposure spot positions 90_{xy} which can be selected in a defined manner, namely when the respective exposure spot 42_{xy} is in the respective exposure spot position 90_{xy}, wherein exposure with an adequate intensity is brought about only in this position on the photosensitive layer 24 by activating the respective exposure beam 66ₓ, i.e., for example, switching on the radiation source associated with the radiation exit 54ₓ, and this intensity brings about a photochemical conversion in the photosensitive layer in the region of this exposure spot 42_{xy}.

If no exposure of the photosensitive layer 24 is provided in the remaining exposure spot positions 90_{xy} within the path of deflection ASₓ, the radiation source associated with the respective radiation exit 54ₓ will not be switched on during the pass through these remaining exposure spot positions 90_{xy} or will be operated with an intensity which cannot lead to any photochemical conversion of the photosensitive layer 24 in the region of the respective exposure spot 42_{xy}.

In order to focus the migrating exposure beams 66 onto the photosensitive layer 24 and, therefore, to adjust the extension of the exposure spots 42 generated by the respective exposure beams 66, an optical unit 100 is provided between the deflecting unit 70 and the photosensitive layer 24 and this optical unit has for each of the exposure beams 66 a separate optical imaging device 104, for example in the form of a lens system, through which the respective migrating exposure beam 66 passes and, therefore, will be focused onto the respective exposure spot 42 with a defined size of the exposure spot 42 as well as a defined intensity distribution in the exposure spot 42 on the photosensitive layer 24.

Advantageous imaging properties of the optical imaging device 104 result, in particular, when the average distance between the operative mirror surface area 78 of the mirror surface 74 corresponds approximately to the focal distance f of the optical imaging device 104 and so the imaging ratios for the migrating exposure beam are essentially identical on account of the telecentric optical device and, therefore, the exposure spots 42 also have essentially the same size and essentially the same intensity distribution (FIG. 6).

Furthermore, it is preferably provided for the distance between the optical imaging device 104 and the photosensitive layer 24 to be exposed to also correspond approximately to the focal distance f of the optical imaging device 104 (FIG. 6) in order to obtain an optimum focusing of the respective exposure beam 66 in the exposure spot 42 on the photosensitive layer 24.

In accordance with the invention, several, for example two, exposure units 50 are associated with each deflecting element 72, namely a first exposure unit 50a and a second exposure unit 50b which direct light on different mirror surfaces 84a and 84b with, for example, the set 61a of first exposure beams 60a and the set 61b of second exposure beams 60b, when they are arranged on different longitudinal sides 79a and 79b of the mirror body 80, in order to obtain sets 61a and 61b of exposure beams 66a and 66b, respectively, which each migrate in the direction of deflection 74.

For example, the exposure units 50a and 50b are arranged relative to the mirror body 80 such that the mirror surfaces 84a and 84b, onto which light is directed, are located on different sides of a plane of symmetry 110 which extends transversely, in particular at right angles, to the photosensitive layer 24 and through the axis 82.

The mirror surfaces 84a and 84b, onto which light is directed, are preferably located in mirror symmetry to the plane of symmetry 110.

As a result of the fact that the mirror surfaces 84a and 84b extend at an angle in opposite directions relative to the photosensitive layer 24 and the sets 61a, 61b of first exposure beams 60a and second exposure beams 60b impinge on them from opposite directions, the exposure spots 42a and 42b generated by such exposure beams 60a, 60b move in a coordinated manner in the direction of deflection 74 when the mirror body 80 is rotated in the direction of rotation 92.

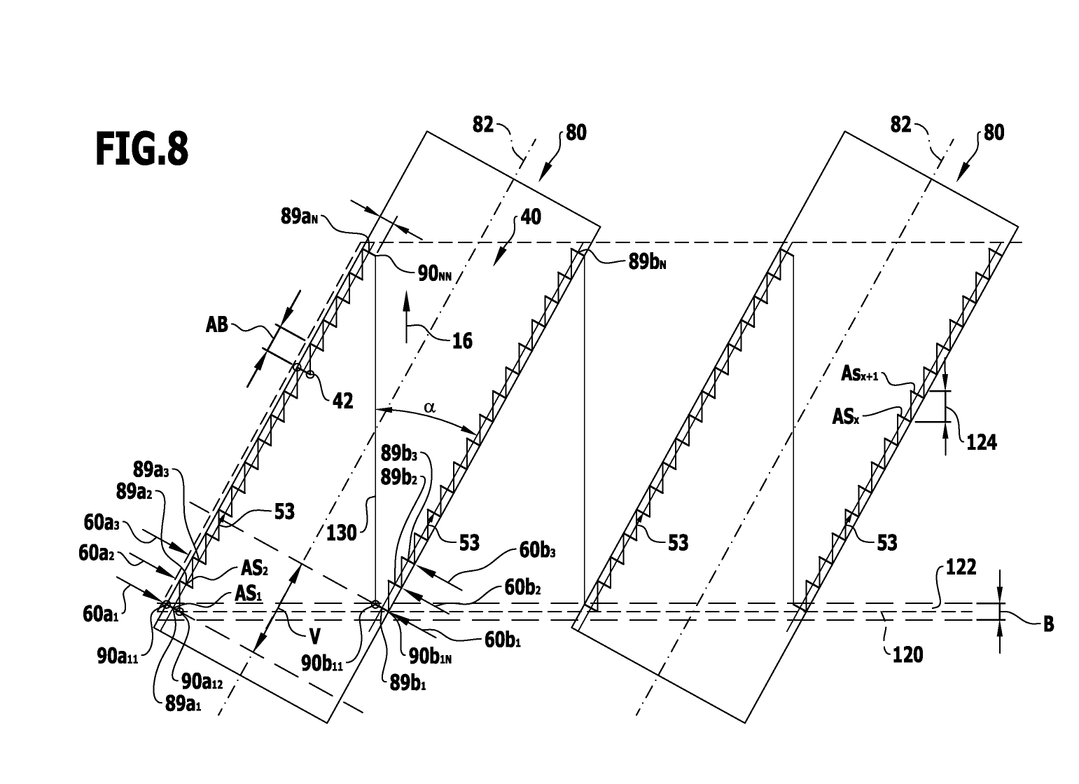

As illustrated in FIG. 8, the sets 61a, 61b of exposure beams 60a and 60b of the exposure units 50a and 50b and, therefore, also the mirror surface areas 89aₓ and 89bₓ, onto which light is directed by these exposure beams 60a, 60b, are arranged relative to one another with an offset V in the direction of the axis 82 of the mirror body 80 and, therefore, also in the direction of the row direction 53 parallel thereto and this offset is a multiple of a distance between the individual exposure beams 60a or 60b of the respective set 61a or 61b and, therefore, also a multiple of a distance AB between two paths of deflection ASₓ and ASₓ₊₁ which follow one another in the row direction 53 and so the exposure spot positions 90aₓₓ and 90bₓₓ which respectively correspond to one another, i.e., for example, the exposure spot positions 90a_{1N} and 90b_{1N}, are arranged within an area of alignment 122 which is located on both sides of a line of alignment 120 extending at right angles to the direction of feed 16 and has in the direction of feed 16 a width B which is smaller than a distance 124 between two consecutive paths of deflection ASₓ and ASₓ₊₁ in the direction of feed 16; the width B of the area of alignment 124 is preferably at the most as large as the extension of an exposure spot 42 and so the line of alignment 120 intersects all the corresponding exposure spots 42a, 42b.

In order to be able to arrange the mirror bodies 80 in a space-saving manner, they are driven about the axis 82 by a drive unit 130 on one side but are rotatably mounted on both sides, wherein the drive units 130 are arranged on respectively opposite sides in the transverse direction 38 transverse to the direction of feed 16 of consecutive mirror bodies 80 and so one drive unit 130 is located in front of the exposure spot 40 in the direction of feed 16 and the next one behind the exposure spot 40 in the direction of feed 16.

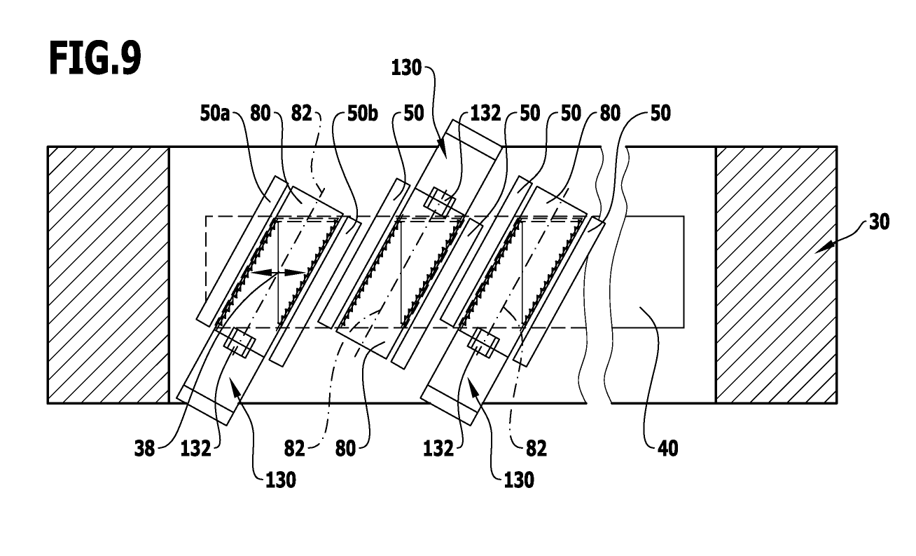

Furthermore, as illustrated in FIGS. 6 and 9, each of the drive units 130 is provided, in addition, with a sensor 132 which is in a position to directly detect the rotary position of the mirror body 80 and therefore, in particular, the position of the mirror surfaces 84 optically, i.e., for example, via a measurement beam 136, which is generated by a radiation source 134, reflected at a mirror surface and impinges on a detector 138, and to transmit this to a control unit designated as a whole as 140.

This control unit 140 activates the drive units 130 such that they rotate with a constant rotational speed and, in addition, controls the illumination of the exposure spots 42.

With respect to the generation of the exposure beams 56, no further details have so far been given.

Preferably, a radiation generating unit 150 is provided separately from the exposure device 30 for generating the exposure beams 56 and this comprises a plurality of radiation sources 152, for example laser diodes, wherein the radiation generated by each of the radiation sources 152 is coupled into a light guide 154 which extends from the radiation generating unit 150 to the exposure device 30 and has an end surface which forms the radiation exit area 54, from which the exposure beams 56 exit.

The arrangement of the radiation generating unit 150 separately from the exposure units 50 has the advantage that, as a result, it is possible to arrange the radiation sources 152 in an optimum manner for their operation and discharge the heat generated by them in an optimum manner without any thermal influence on the exposure device 30 being able to take place as a result.

On the contrary, the exposure device 30 and the photosensitive layer 24 are thermally decoupled from the radiation generating unit 150 completely and, as a result, there is no risk of any impairment to the precision in the region of the exposure device 30 on account of thermal effects caused by the radiation generating unit 150.

The radiation generating unit 150 can be arranged at a distance above the exposure device 30 but it is also possible, when the light guides 154 are of a sufficiently long design, to arrange the radiation generating unit 150 to the side of the machine base 10, for example next to the control unit 140.

As already explained, it is possible for the radiation generating unit 150, on the one hand, to detect exactly the rotary position of the respective mirror body 80 via the sensors 132 which are associated with the respective drive unit 130 and, therefore, to be able to determine which area of the mirror surface 84 is the actively used area, in which exposure spot position 90 the exposure spot 42 respectively generated is located along the path of deflection AS at the respectively determined point in time and, therefore, to decide whether an exposure of the photosensitive layer 24 should be carried out in this exposure spot position 90 or not and, in accordance with this decision, to activate the radiation source 152 which is provided for generating the respective exposure spot 42 such that this supplies radiation which triggers a photochemical effect in the photosensitive layer 24 in the region of the exposure spot 42 or to switch it off or with respect to its intensity to reduce it to such an extent that no photochemical effect occurs in the region of the exposure spot 42 located in the respective exposure spot position 90.

In order not only to be able to position the individual exposure spots 42 in the individual exposure spot positions 90 within the path of deflection AS such that they—for the production of coherent structures 26 extending at least with one component in the transverse direction—overlap in order to be able to generate the coherent structure 26 by means of a plurality of individual exposure spots 42 but also to arrange the exposure spots 42, which can be generated by exposure beams 66 following one another in the row direction 53, so that they overlap, the row direction 53 extends relative to the direction of feed 16 at an angle α such that a straight reference line 160 through the last exposure spot position 90_{1N} of the, for example, first exposure beam 66₁ of an exposure unit 50, this straight reference line being parallel to the direction of feed 16, touches, preferably intersects the exposure spot 42₂₁ in the first exposure spot position 90₂₁ of the next exposure beam 66₂ following on in the row direction 53 so that as a result of movement of the last exposure spot 42_{1N} in the direction of feed 16 as far as the feed position of the first exposure spot 42₂₁ of the next following exposure beam 66₂ the two exposure spots 42_{1N} and 42₂₁ can be arranged so as to overlap with one another and, therefore, the exposure spots 42₂ of the second exposure beam 66₂ can also be used to generate the coherent structure 26 together with the exposure spots 42₁ of the first exposure beam 66₁.

This relative arrangement of the respectively last exposure spot 42_{xN} of one exposure beam 66ₓ relative to the respectively first exposure spot 42ₓ₊₁ of the next following exposure beam 66ₓ₊₁ is provided for all the exposure beams 66 and exposure spots 42 of an exposure unit 50 and so theoretically all the exposure spots 42 of this exposure unit 50 can be used to generate a coherent structure 26 extending with a component in the transverse direction 38 over the entire extension of the set 61 of exposure beams 60 of this exposure unit 50 in the transverse direction 38.

In the same way as that described in conjunction with the arrangement of the exposure spots 42, generated by different exposure beams 66 of the respective set 61, the first and second exposure units 50a, 50b etc. are also arranged relative to one another such that, as illustrated, for example, in FIG. 3, a straight reference line 170 through the last exposure position 90_{NN} of a first exposure unit 50, for example the exposure unit 50a, this reference line being parallel to the direction of feed 16, touches or intersects the exposure spot 42_{b11} of the first exposure position 90_{b11} of the next exposure unit following on in the transverse direction 38, for example the exposure unit 50b, and so the exposure spots 42 which can be generated by all the exposure units following one another in the transverse direction 38, for example the exposure units 50a and 50b, can also be used for generating a coherent structure 26 due to the fact that the exposure spots 42 of one exposure unit 50, for example the exposure unit 50a, are positioned so as to overlap and the last exposure spot 42_{NN} of the last exposure beam 66_{N} can be arranged so as to overlap with the first exposure spot 42₁₁ of the first exposure beam 66₁ of the next exposure unit following on in the transverse direction 38, for example the exposure unit 50b.

On the condition that the exposure area 40 extends in the transverse direction 38 over the entire width of the photosensitive layer 24 or at least over an area of the photosensitive layer 24 provided for the exposure and generation of structures 26, coherent or also non-coherent structures 26 can be generated in the entire area of the photosensitive layer 24 covered by the exposure area 40.

Since all the exposure units 50 of the exposure device 30 are arranged relative to one another in such a manner, it is possible to generate coherent structures 26 which are of an optional design in optional areas on the photosensitive layer 24 over its entire transverse direction 38 and over the entire longitudinal direction 36 using the feeding movement 16 and these structures can extend not only in the longitudinal direction 36 but also in the transverse direction 38 or at any angle relative to them.

For this purpose, the control unit 150 detects not only the position of the photosensitive layer 24 in the direction of feed 16 by detecting the position of the object carrier 14 but also the positions of the individual exposure spots 42 which can be generated along the path of deflection AS as a result of the rotary position of the mirror body 80 and is, therefore, in a position to generate an exposure spot 42, in addition, at any location of the exposure area 40 provided on the photosensitive layer 24 as a result of suitable activation of the respective radiation source 152 at the suitable point of time, wherein this preferably takes place as a result of suitable activation of the radiation sources 152 during the course of a single movement of the object carrier 14 in the direction of feed 16.

It is favorable for an adequate preciseness during the positioning of the exposure spots 42 for generating the structures 26 when the speed in the direction of feed 16 is only so great that the exposure spots 42 generated by two mirror surface areas 88, which follow one another in the circumferential direction 86, by way of one exposure beam 66 are offset relative to one another at the most by half a diameter, even better through values in the range of a fifth to a tenth of the diameter of the exposure spots 42, i.e. they overlap to a considerable extent.

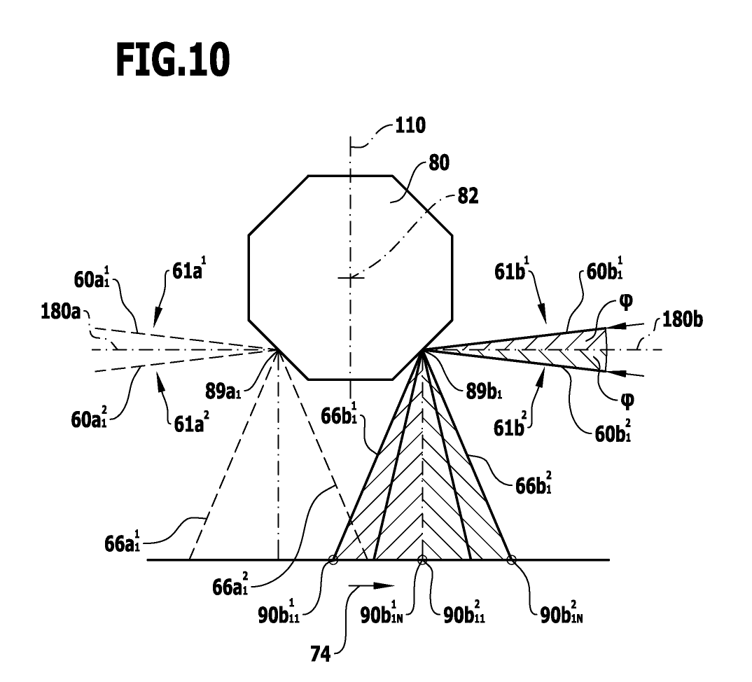

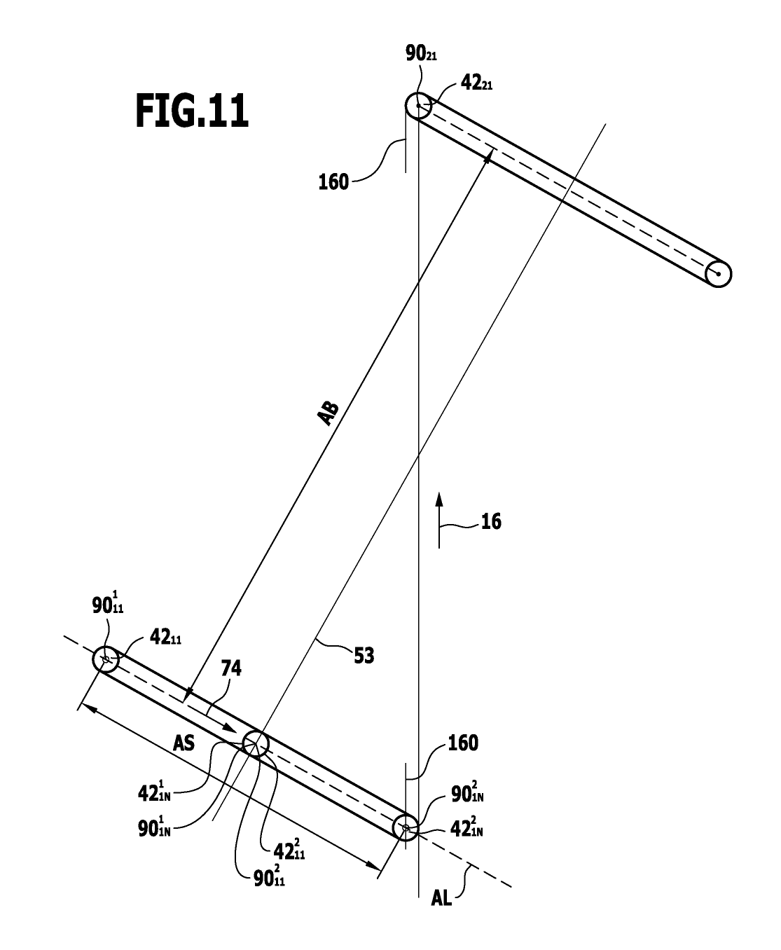

In a second embodiment of an exposure system according to the invention, illustrated in FIGS. 10 and 11, an exposure beam 60¹ and an exposure beam 60² from two sets 61¹ and 61² of second exposure beams 60b impinge each time on the respective mirror surface area 89, for example the mirror surface area 89b₁, and they are deflected by the same mirror surface area 89b₁ such that the exposure spots 42¹₁₁ and 42²₁₁ can be generated in the exposure spot positions 90¹₁₁ and 90²₁₁ and then the additional exposure spots 42¹₁ₓ and 42²₁ₓ as far as the exposure spots 42¹_{1N} and 42²_{1N} in the exposure spot positions 90¹_{1N} and 90²_{1N}, wherein the exposure spots 42¹₁ₓ are located in one section and the exposure spots 42²₁ₓ in an additional section on the same line of deflection AL and the exposure spots 42¹_{1N} and 42¹₁₁ are arranged so as to overlap at least partially so that—as in the first embodiment—a coherent area of the photosensitive layer 24 can be exposed in the transverse direction 38 along the respective path of deflection AS as a result of the overlapping of exposure spots 42¹₁ₓ and 42²₁ₓ which are located next to one another.

The exposure beams 60¹ and 60² consisting of the sets 61¹ and 61² preferably each extend at an angle φ to a central axis 180, i.e. they form an angle of 2φ with one another, whereas the angle of deflection, which is generated by the mirror body 80 on account of the actively used area of the mirror surfaces 84 and through which each of the exposure beams 66¹₁ and 66²₁ is moved about the axis 82 during the rotation of the mirror body 80, is likewise 2φ.

It is, therefore, possible to bring about exposure in an area-covering manner in the entire exposure area 40 even during small movements in the direction of deflection 74 along the paths of deflection AS.

In the second embodiment, as well, several sets 61 of first exposure beams 60a and second exposure beams 60b can impinge on the mirror body 80 from various sides of the plane of symmetry 110 in order to be deflected by it, as described in the first embodiment.

With respect to the basic construction of the exposure system and the remaining features, reference is made to the comments on the first embodiment.

1. Exposure system for generating exposed structures in a photosensitive layer arranged on an object, comprising an object carrier accommodating the object and an exposure device, wherein the object carrier and the exposure device are movable relative to one another in a direction of feed and wherein exposure spots are generatable on the photosensitive layer with the exposure device transversely to the direction of feed in a position controlled manner in that the exposure device has at least one exposure unit with a row of radiation exit areas arranged to follow one another in a row direction, exposure beams exiting from said radiation exit areas, an exposure spot being generatable with each of said exposure beams on the photosensitive layer by means of an imaging unit and each of said exposure beams being deflectable in a direction of deflection extending transversely to the row direction and at an angle to the direction of feed by means of at least one deflecting unit having a deflecting element moving in a direction of movement and having at least one reflector surface so that with each exposure beam exposure spots overlapping one another at least partially are generatable in the direction of deflection in a plurality of consecutive exposure spot positions,
at least one first exposure unit generating a set of first exposure beams and at least one second exposure unit generating a set of second exposure beams are associated with the at least one deflecting element, the first and second exposure beams of said exposure units being deflectable by the same deflecting element during its movement, the movable deflecting element being provided with at least one mirror surface area for each first and for each second exposure beam from the respective first set and second set and the mirror surface areas for the first exposure beams and the mirror surface areas for the second exposure beams are arranged on the deflecting element so as to be offset relative to one another in the row direction.

2. Exposure system as defined in claim 1, wherein the mirror surface areas have an offset in the row direction corresponding at least to a distance between two consecutive exposure beams of one set of exposure beams.

3. Exposure system as defined in claim 2, wherein the offset corresponds to a multiple of the distance between two consecutive exposure beams.

4. Exposure system as defined in claim 1, wherein the deflecting elements are mounted on oppositely located sides.

5. Exposure system as defined in claim 4, wherein the deflecting elements are adapted to be driven by a drive device on one side.

6. Exposure device as defined in claim 1, wherein deflecting elements arranged so as to follow one another in a transverse direction extending transversely to the direction of feed are adapted to be driven alternatingly with a drive device on respective, oppositely located sides.

7. Exposure system as defined in claim 1, wherein the mirror surface areas of the first and second exposure beams of the first and second exposure units are arranged with respect to an area of alignment on the photosensitive layer extending at right angles to the direction of feed such that one of the exposure spot positions of one of the paths of deflection of the first exposure unit and an exposure spot position corresponding thereto of the corresponding path of deflection of the second exposure unit are located in this area of alignment.

8. Exposure system as defined in claim 7, wherein the area of alignment has in the direction of feed an extension corresponding to a distance between the last exposure spot position of one of the paths of deflection and the first exposure spot position of the next one of the paths of deflection of a set of exposure beams.

9. Exposure system for generating exposed structures in a photosensitive layer arranged on an object, comprising an object carrier accommodating the object and an exposure device, wherein the object carrier and the exposure device are movable relative to one another in a direction of feed and wherein exposure spots are generatable on the photosensitive layer with the exposure device transversely to the direction of feed in a position controlled manner in that the exposure device has at least one exposure unit with a row of radiation exit areas arranged to follow one another in a row direction, exposure beams exiting from said radiation exit areas, an exposure spot being generatable with each of said exposure beams on the photosensitive layer by means of an imaging unit and each of said exposure beams being deflectable in a direction of deflection extending transversely to the row direction and at an angle to the direction of feed by means of at least one deflecting unit having a deflecting element moving in a direction of movement and having at least one reflector surface so that with each exposure beam exposure spots overlapping one another at least partially are generatable in the direction of deflection in a plurality of consecutive exposure spot positions, at least one first exposure unit generating a set of first exposure beams and at least one second exposure unit generating a set of second exposure beams are associated with the at least one deflecting element, the first and second exposure beams of said exposure units being deflectable by the same deflecting element during its movement, and the first and the second exposure beams impinge on the photosensitive layer offset relative to one another in a row direction extending transversely to the direction of movement.

10. Exposure system as defined in claim 9, wherein all the exposure units of the exposure device are arranged relative to one another such that exposure spot positions of corresponding paths of deflection, said spot positions corresponding to one another, are located on the photosensitive layer in an area of alignment extending at right angles to the direction of feed.

11. Exposure system as defined in claim 10, wherein the area of alignment has in the direction of feed an extension corresponding to a distance between the last exposure spot position of one of the paths of deflection and the first exposure spot position of the next following path of deflection of one of the exposure units in the direction of feed.

12. Exposure system as defined in claim 1, wherein exposure spot positions of the first and second sets of exposure beams respectively corresponding to one another have a distance from a line of alignment corresponding at the most to the diameter of an exposure spot of the exposure spot position, said line of alignment extending at right angles to the direction of feed.

13. Exposure system as defined in claim 1, wherein a line of alignment extending through one of the exposure spot positions of one of the paths of deflection of the first exposure unit and being aligned at right angles to the direction of feed intersects an exposure spot position of the corresponding path of deflection of the second exposure unit corresponding to it.

14. Exposure system as defined in claim 1, wherein the at least one set of first exposure beams impinges on one of the longitudinal sides of the deflecting element and the at least one set of second exposure beams impinges on a longitudinal side located opposite the one longitudinal side.

15. Exposure system for generating exposed structures in a photosensitive layer arranged on an object, comprising an object carrier accommodating the object and an exposure device, wherein the object carrier and the exposure device are movable relative to one another in a direction of feed and wherein exposure spots are generatable on the photosensitive layer with the exposure device transversely to the direction of feed in a position controlled manner in that the exposure device has at least one exposure unit with a row of radiation exit areas arranged to follow one another in a row direction, exposure beams exiting from said radiation exit areas, an exposure spot being generatable with each of said exposure beams on the photosensitive layer by means of an imaging unit and each of said exposure beams being deflectable in a direction of deflection extending transversely to the row direction and at an angle to the direction of feed by means of at least one deflecting unit having a deflecting element moving in a direction of movement and having at least one reflector surface so that with each exposure beam exposure spots overlapping one another at least partially are generatable in the direction of deflection in a plurality of consecutive exposure spot positions, one exposure beam of each of at least two sets of exposure beams impinging on the same mirror surface area of the deflecting element and is reflected by it onto the photosensitive layer.

16. Exposure system as defined in claim 15, wherein the at least two exposure beams impinge on the mirror surface area at an acute angle to one another.

17. Exposure system as defined in claim 16, wherein the at least two exposure beams extend symmetrically to a central axis.

18. Exposure system as defined in claim 15, wherein the at least two exposure beams generate on the photosensitive layer exposure spots with paths of deflection located on a common line of deflection.

19. Exposure system as defined in claim 17, wherein the exposure spots of one of the at least two exposure beams are located on one section of the line of deflection and the exposure spots of the other one of the at least two exposure beams are located on another section of the line of deflection.

20. Exposure system as defined in claim 18, wherein the last exposure spot of the one exposure beam is arranged in such a manner that it overlaps with the first exposure spot of the other exposure beam.

21. Exposure system as defined in claim 18, wherein the at least two exposure beams result in exposure spots with respectively adjacent exposure spots thereof overlapping at least partially.

22. Exposure system as defined in claim 1, wherein the exposure spots of consecutive exposure beams are movable along directions of deflection parallel to one another.

23. Exposure system as defined in claim 1, wherein the exposure beams of the at least one exposure unit are deflectable by the deflecting unit at the same time and to the same extent.

24. Exposure system as defined in claim 1, wherein the exposure beams of one exposure unit impinge on the photosensitive layer aligned essentially parallel to one another.

25. Exposure system as defined in claim 1, wherein the movement of each exposure spot generated by an exposure beam is brought about in the respective direction of deflection via a path of deflection approximately of the same length for each exposure beam of the exposure unit.

26. Exposure system as defined in claim 1, wherein the exposure spot of the last exposure spot position of the one path of deflection and the exposure spot of the first exposure spot position of the next following path of deflection are arranged with respect to a straight reference line extending parallel to the direction of feed in such a manner that the straight reference line intersects the exposure spots generated in these exposure spot positions.

27. Exposure system as defined in claim 1, wherein a straight reference line extending parallel to the direction of feed through the last exposure spot position of a path of deflection intersects the exposure spot of a first exposure spot position of a next following path of deflection.

28. Exposure system as defined in claim 27, wherein the first exposure spot position of the next following path of deflection has a distance from the straight reference line corresponding at the most to half the diameter of the exposure spot.

29. Exposure system as defined in claim 1, wherein several exposure units are provided, the exposure units being arranged at a distance from one another in the direction of deflection.

30. Exposure system as defined in claim 29, wherein the directions of deflection of the several exposure units extend essentially parallel to one another.

31. Exposure system as defined in claim 29, wherein the row directions of the several exposure units extend essentially parallel to one another.

32. Exposure system as defined in claim 29, wherein the several exposure units are arranged with respect to a straight reference line extending parallel to the direction of feed such that the straight reference line intersects the exposure spot of the last exposure spot position of the last path of deflection of one exposure unit and the exposure spot of the first exposure spot position of the first path of deflection of a next following exposure unit.

33. Exposure system as defined in claim 1, wherein the straight reference line extending through the last exposure spot position of a last path of deflection of one exposure unit intersects the exposure spot of the first exposure spot position of the first path of deflection of a next following exposure unit.

34. Exposure system as defined in claim 15, wherein the first exposure spot position has a distance from the straight reference line corresponding at the most to half the diameter of the exposure spot of the first exposure spot position.

35. Exposure system as defined in claim 1, wherein the mirror surface areas are sections of a common mirror surface.

36. Exposure system as defined in claim 1, wherein the mirror surface areas are tiltable onto the exposure beams relative to the direction of impingement thereof.

37. Exposure system as defined in claim 1, wherein the mirror surface areas are flat surface areas.

38. Exposure system as defined in claim 37, wherein all the mirror surface areas are located in a common plane.

39. Exposure system as defined in claim 37, wherein the mirror surface areas impinged upon by the exposure beams of one exposure unit are located in the same plane.

40. Exposure system as defined in claim 1, wherein the deflecting element has several mirror surface areas for each exposure beam.

41. Exposure system as defined in claim 40, wherein for each exposure beam the deflecting unit has several mirror surface areas used one after the other.

42. Exposure system as defined in claim 1, wherein the several mirror surface areas are formed by circumferential sides of a mirror body arranged so as to be rotatable.

43. Exposure system as defined in claim 42, wherein the mirror body is arranged so as to rotate about an axis.

44. Exposure system as defined in claim 42, wherein the mirror surface areas are arranged at the same radial distance around the axis.

45. Exposure system as defined in claim 42, wherein the mirror body rotates about its axis with a constant rotational speed.
